(19) United States
(12) Patent Application Publication
(10) Pub. No.: US 2024/0338570 A1
(43) Pub. Date: Oct. 10, 2024

(54) DEEP REINFORCEMENT LEARNING INTELLIGENT DECISION-MAKING PLATFORM BASED ON UNIFIED ARTIFICIAL INTELLIGENCE FRAMEWORK

(71) Applicant: Anhui University, Hefei (CN)

(72) Inventors: Changyin SUN, Hefei (CN); Wenzhang LIU, Hefei (CN); Chaoxu MU, Hefei (CN); Lu REN, Hefei (CN); Zhuoran SHI, Hefei (CN)

(21) Appl. No.: 18/747,561

(22) Filed: Jun. 19, 2024

(30) Foreign Application Priority Data
Oct. 17, 2023 (CN) 202311338634.3

(51) Int. Cl. G06N 3/092

(52) U.S. Cl. CPC G06N 3/092

(57) ABSTRACT

A deep reinforcement learning (DRL) intelligent decision-making platform based on a unified AI framework includes a parameter configuration module, a general-purpose module, an original environment module, an environment vectorization module, an environments maker, a mathematical utilities module, a model library and a runner. Parameters of a DRL model are selected through the parameter configuration module, and read by the general-purpose module. Based on the read parameters, a representer, a policy module, a learner, and an intelligent agent are called from the model library and created, where necessary function definitions and optimizers are called from the mathematical utilities module. Based on the read parameters, the environment vectorization module is created based on the original environment. The intelligent agent and environments are input into the runner to compute an action output, which executes the action output to realize the intelligent decision making.

### CROSS-REFERENCE TO RELATED APPLICATIONS

This application claims the benefit of priority from Chinese Patent Application No. 202311338634.3, filed on Oct. 17, 2023. The content of the aforementioned application, including any intervening amendments thereto, is incorporated herein by reference in its entirety.

### TECHNICAL FIELD

This application relates to artificial intelligence (AI), and more particularly to a deep reinforcement learning (DRL) intelligent decision-making platform based on a unified artificial intelligence (AI) framework.

### BACKGROUND

As an important tool in the artificial intelligence, Deep Reinforcement Learning (DRL) has been widely recognized in decision tasks in recent years such as Go games, video games, and recommendation algorithms, and therefore has attracted extensive attention from both academia and industry. Extensive DRL-based intelligent decision-making algorithms for different tasks have been emerging. However, these algorithms are usually implemented based on different AI programming frameworks, and there is incompatibility between the use of software versions, thus hindering the secondary development. In addition, the current deep reinforcement learning involves various algorithmic structures, so how to establish a unified framework that can include mainstream reinforcement learning algorithms as comprehensively as possible is an extremely challenging problem.

Several DRL-based decision-making platform involving multiple algorithms, such as Rllib developed by University of California, Berkeley, ChainerRL jointly released by Preferred Networks and University of Tokyo, and Tianshou developed by Tsinghua University, have been proposed. These decision-making platforms provide dozens of implementation examples of the deep reinforcement learning algorithm, and can perform underlying encapsulation of common functions, thereby improving the developer's efficiency to a certain extent. However, they also have some obvious shortcomings. For example, Rllib is highly encapsulated and not modularised enough, making it difficult for users to customize the decision tasks and algorithmic structures quickly and flexibly; ChainerRL is a reinforcement learning library designed specifically for the Chainer framework, thereby limiting its versatility; Tianshou is a highly modularized open-source reinforcement learning platform, but only supports the PyTorch framework, so it cannot meet the needs of users of other AI frameworks. In summary, there is a lack of a DRL-based decision-making platform compatible with multiple AI programming frameworks while ensuring the number of algorithms and functional diversity. Therefore, there is an urgent need to design a deep reinforcement learning decision-making platform based on a unified AI framework.

### SUMMARY

In view of the deficiencies in the prior art, this application provides a deep reinforcement learning (DRL) intelligent decision-making platform based on a unified AI framework, in which DRL models with different functions and structures are reasonably classified, and subjected to the unified modular design, thereby allowing for good compatibility with various AI frameworks.

Technical solutions of this application are described as follows.

In a first aspect, this application provides a deep reinforcement learning intelligent decision-making platform based on a unified artificial intelligence (AI) framework, comprising:
a parameter configuration module;
a general-purpose module;
an original environment module;
an environment vectorization module;
an environments maker;
a mathematical utilities module;
a model library; and
a runner;
wherein the parameter configuration module is connected to the general-purpose module; the general-purpose module is connected to the model library, the original environment module and the runner; the original environment module, the environment vectorization module, and the environments maker are connected in turn; the environments maker is connected to the runner; and the mathematical utilities module is connected to the model library;
the parameter configuration module is configured to select parameters of a deep reinforcement learning model, comprising an intelligent agent name, a representer name, a policy name, a learner name, an algorithmic parameter, an environment name, and a system parameter;
the general-purpose module is configured to read the parameters of the deep reinforcement learning model; call and create a representer, a policy module, a learner, and an intelligent agent from the model library according to the parameters; and call a necessary function definition and an optimizer from the mathematical utilities module during a process of creating the policy module and the learner;
the environment vectorization module is configured to create parallel environments based on an original environment according to the parameters;
the environments maker is configured to make the parallel environments to obtain the made environments, and input the made environments and the intelligent agent into the runner; and
the runner is configured to compute an action output, and execute the action output in the made environments to realize intelligent decision-making.

In an embodiment, the parameter configuration module is also configured to configure parameters involved in decision-making algorithms and tasks in a YAML format, and transfer configured parameters to the general-purpose module.

In an embodiment, the general-purpose module is configured to store a programming module required by different decision-making algorithms for solving different decision-making problems; the general-purpose module is provided with the YAML file reading module, a terminal command reading module and an empirical data pool; the YAML file reading module is configured to read a YAML file in the parameter configuration module, transfer a parameter read from the YAML file to the intelligent agent and the runner, transfer the parameter to the learner, the policy module, and the representer in turn through the intelligent agent, and transfer the parameter to the environments maker, the environment vectorization module, and the original environment module through the runner; the terminal command reading module is configured to read a terminal command to support user's interaction with the deep reinforcement learning intelligent decision-making platform; the empirical data pool is configured to store and manage empirical data from environment interactions; the empirical data pool is configured to be associated with the learner through the intelligent agent to support an experience replay training and optimization process of the learner.

In an embodiment, the model library is configured to provide a user with the deep reinforcement learning model, and customize and optimize the deep reinforcement learning model according to different scenarios and task requirements.

In an embodiment, the model library consists of the representer, the policy module, the learner, and the intelligent agent; the representer is configured to be determined based on a representation parameter read by a YAML file reading module, and convert raw observation data in the made environments into a feature suitable for being processed by the deep reinforcement learning model for representation; the policy module is configured to determine a policy based on a policy parameter read by the YAML file reading module, and formulate a decision-making behavior adopted by the intelligent agent with the feature calculated by the representer as an input; the decision-making behavior comprises an action selection policy and an environment interaction mode; the learner is configured to be determined based on a learner parameter read by the YAML file reading module, formulate a learning rule based on empirical data and the action selection policy, so as to obtain an action-selection policy; the intelligent agent is configured to be determined based on an agent parameter read by the YAML file reading module, output an action and execute the decision-making behavior using the action-selection policy of the learner, and interact with a simulation environment.

In an embodiment, the original environment module is configured to store original environment definitions for different simulation environments, comprising parameter acquisition, environment reset, action execution, environment rendering and global state acquisition functions of the original environment, and provide the environment vectorization module, the environments maker, the intelligent agent and the policy module with a basic tool and parameters for simulation environment interaction.

In an embodiment, the environment vectorization module is configured to randomly create a plurality of environments to run in parallel according to the original environment to interact with the intelligent agent.

In an embodiment, the environments maker is configured to make a specific simulation environment according to the simulation scenarios and task requirements, to interact with the intelligent agent.

In an embodiment, the mathematical utilities module is configured to unifiedly encapsulate nonlinear functions, optimizers, and filters involved in various deep reinforcement learning models, and is responsible for probability distribution-related calculations in the policy module, and functions in the learner involving the optimizer.

In an embodiment, the runner is configured to have a training mode and a test mode; the training mode is configured to make the parallel environments and the intelligent agent through a run method to train the deep reinforcement learning model, so as to produce a training result; and the test mode is configured to make the parallel environments and the intelligent agent through a benchmark method to enable performance testing of the deep reinforcement learning model, so as to produce a performance testing result.

Compared to the prior art, this application has the following beneficial effects.

Regarding the deep reinforcement learning intelligent decision-making platform based on a unified AI framework provided in this application, various functions involved in the deep reinforcement learning model are modularized to achieve the compatibility with different AI frameworks. This application is compatible with three AI frameworks, namely PyTorch, TensorFlow and MindSpore, and new deep reinforcement learning models and new tasks can be continuously introduced. Currently, this application has supported more than thirty types of deep reinforcement learning models and more than one hundred types of decision-making tasks. At the same time, this application extracts separately the model library in the decision-making platform that has nothing to do with the AI framework, and carries out standardized encapsulation of the decision-making scenarios and tasks, common tools, and parameter reading, so that the user can quickly establish his/her own scenarios and tasks on the platform and freely design the structure of the deep reinforcement learning model, which can greatly improve the development efficiency of the deep reinforcement learning model.

### BRIEF DESCRIPTION OF THE DRAWINGS

FIG. 1 is a framework diagram of a deep reinforcement learning intelligent decision-making platform based on a unified AI framework according to an embodiment of the disclosure.

### DETAILED DESCRIPTION OF EMBODIMENTS

The technical solutions of the disclosure will be further described below in conjunction with the accompanying drawings and embodiments.

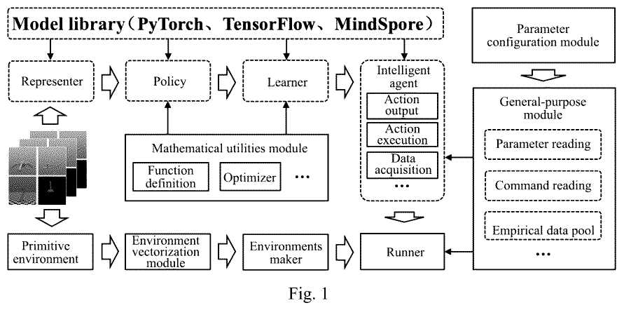

As shown in FIG. 1, a deep reinforcement learning intelligent decision-making platform based on a unified AI framework includes a parameter configuration module, a general-purpose module, an original environment module, an environment vectorization module, an environments maker, a mathematical utilities module, a model library, and a runner. The parameter configuration module is connected to the general-purpose module. The general-purpose module is connected to the model library, the original environment module, and the runner, respectively. The original environment module, the environment vectorization module, and the environments maker are connected in turn. The environments maker is connected to the runner. The mathematical utilities module is connected to the model library. The parameter configuration module is configured to select parameters of a deep reinforcement learning model. The selected parameters include an intelligent agent name, a representer name, a policy name, a learner name, an algorithmic parameter, an environment name, and a system parameter. The system parameter includes a selection of CPU/GPU, a model storage address, and a log file storage address. The general-purpose module is configured to read the parameters of the deep reinforcement learning model. Further, according to the read parameters, the general-purpose module calls and creates a representer, a policy module, a learner, and an intelligent agent from the model library. The general-purpose module calls a necessary function definition and an optimizer from the mathematical utilities module during a process of creating the policy module and the learner. According to the parameters, the environment vectorization module is configured to create parallel environments based on the original environment. The environments maker is configured to make the parallel environments to obtain made environments and input the made environments and the intelligent agent into the runner. The runner is configured to compute an action output and execute the action output in the made environments to realize an intelligent decision-making. In this disclosure, deep reinforcement learning models with different functions and structures are reasonably classified and subjected to the unified modular design, thereby allowing for good compatibility with various AI frameworks. In addition, the disclosure separately extracts the model library in the decision-making platform that is unrelated to the AI framework, and carries out standardized encapsulation of decision scenarios and tasks, common tools, and parameter reading, so that the user can quickly establish his/her own scenarios and tasks and freely design the structure of the deep reinforcement learning model in the platform, thereby greatly enhancing the development efficiency of the deep reinforcement learning model.

The parameter configuration module is responsible for configuring various parameters involved in the decision-making algorithms and tasks in a YAML format, and transferring the configured parameters to the general-purpose module, which facilitates the debugging of the parameters by the technicians. The debugging of the parameters of different decision-making algorithms and different tasks is not affected by each other. In order to further facilitate debugging by technicians, the configured parameters in the parameter configuration module are divided into basic parameters and algorithmic parameters. The basic parameters mainly affect the runner through the general-purpose module. The basic parameters include CPU/GPU selection, AI framework selection, and training mode and visualization mode configuration. The algorithmic parameters affect an intelligent agent module, a learner module, a policy module, and a representer module. The algorithmic parameters include task selection, model selection, learning rate, discount factor, and learning step parameter configuration, wherein the model selection includes intelligent agent selection, learner selection, policy selection, and representer selection.

The general-purpose module is used to support the normal operation of other modules. The general-purpose module works in concert with the parameter configuration module to ensure that the required tools and resources are shared among the modules, which is used to store the programming modules required for different decision-making algorithms to solve different decision-making problems, thereby reducing the code rewriting rate. The general-purpose module is equipped with a YAML file reading module, a terminal command reading module, and an empirical data pool. The YAML file reading module is responsible for reading the YAML file in the parameter configuration module, then transferring the parameters read from the YAML file to the intelligent agent and the runner, then transferring the parameters to the learner, the policy module, and the representer in turn through the intelligent agent, and then transferring the parameters through the runner to the environments maker, environment vectorization module and original environment module, so as to ensure that the settings of the parameters in the intelligent decision-making platform remain consistent. The terminal command reading module is used to read terminal commands to support the user's interactions with the deep reinforcement learning intelligent decision-making platform, which is associated with the runner and allows the user to set the parameters in the runner through the terminal commands, thereby affecting the decision and the behaviors of the deep reinforcement learning model. The empirical data pool is used to store and manage empirical data from environmental interactions. The empirical data pool is associated with the learner via the intelligent agent to support data collection and experience replay. The intelligent agent provides the empirical replay data to the learner for the training and optimization process of the learner. The implementation of the general-purpose module in the disclosure does not involve a specific AI framework, so the general-purpose module is shared for other modules under the three frameworks of PyTorch, TensorFlow and MindSpore, which effectively reduces the overall code size.

The model library in the disclosure provides users with abundant deep reinforcement learning models, thereby allowing users to freely match and select deep reinforcement learning models, and customize and optimize deep reinforcement learning models according to different scenarios and task requirements. The model library consists of the representer, the policy module, the learner, and the intelligent agent.

The representer is configured to be determined based on the representation parameters read by the YAML file reading module, and convert the raw observation data in the made environment into features suitable for being processed by the deep reinforcement learning model for representation. The representer may process different forms of raw observation data including, but not limited to, images, one-dimensional vectors, and sequential observation inputs. The representers in the disclosure include four types of equivalent representations (raw observations are not processed), multilayer perceptron (MLP), convolutional neural network (CNN), and recurrent neural network (RNN). The RNN is further divided into two implementations, long short-term memory (LSTM) and Gate Recurrent Unit (GRU). As shown in Table 1, the MLP is suitable for one-dimensional vector inputs, the CNN is suitable for image inputs, and the RNN is suitable for sequence observation inputs. In addition, RNN needs to be used in combination with MLP and CNN, such as MLP+RNN, CNN+RNN, and the user needs to customize the RNN representer according to the task requirements. The disclosure implements the representers under three AI frameworks, such as PyTorch, TensorFlow and MindSpore.

TABLE 1
Corresponding relationship between representation
parameters and representers

| Representation parameter | Corresponding representer |
|---|---|
| Basic_Identical | Equivalent representation |
| Basic_MLP | MLP |
| Basic_CNN | CNN |
| Basic_RNN | RNN |

The policy module determines the policy based on the policy parameter read by the YAML file reading module, and formulates the decision-making behaviors adopted by the intelligent agent with the feature calculated by the representer as an input. The decision-making behavior includes an action selection policy and an environment interaction mode. The policy module includes various policies which are classified according to the number of intelligent agents, the form of action output, and the nature of the task. In the disclosure, the policy module is classified into a single intelligent agent policy and a multi-intelligent agent policy according to the number of intelligent agents, which are applied to single intelligent agent deep reinforcement learning and multi-intelligent agent reinforcement learning, respectively. The policy module is classified into a deterministic policy, a discrete probability distribution policy, and a Gaussian policy according to the form of the action output. The deterministic policy directly outputs the action values according to the output results of the representer. The discrete probability distribution policy outputs the probability value of each action. The Gaussian policy outputs a probability distribution from which the intelligent agent will randomly sample actions. The policy is selected based on the own characteristics of the deep reinforcement learning model and the nature of the task, thereby selecting the policy name by specifying the policy parameter. The disclosure implements the policy module under all three AI frameworks, such as PyTorch, TensorFlow, and MindSpore.

The learner is determined based on the learner parameter read by the YAML file reading module, and formulates the learning rule based on the empirical data and the action selection policy of the policy module, so as to obtain an action-selection policy and transfer the action-selection policy to the intelligent agent. The selection way and the execution way of policy directly affect the training and optimization process of the learner, while the learner calculates the loss function and updates the model parameters by receiving the empirical data provided by the intelligent agent and the feedback information from the environment. Through the effective management of the learner module and the collaborative work of the learner module, the policy module and the intelligent agent, the deep reinforcement learning model can continuously optimize the policy of the intelligent agent, adapt to various tasks and environments, and improve the performance and robustness of the decision-making platform. The disclosure embodies the policy update method of each deep reinforcement learning model in the learner, where the neural network output is computed based on the empirical replay data provided by the intelligent agent module. The learner is the key to the successful operation of the deep reinforcement learning model. In the disclosure, one learner is configured for each type of reinforcement learning model. The disclosure implements learners under all three AI frameworks, such as PyTorch, TensorFlow, and MindSpore.

The intelligent agent is determined based on the agent parameters read by the YAML file reading module, outputs actions and performs decision-making behaviors using the action-selection policy of the learner, and interacts with the simulation environment. In the initialization procedure of the module, the key parts of the representer, the policy, the learner and the empirical replay pool are instantiated. The disclosure associates the module with the environments maker through the runner, so as to interact with the instantiated simulation environment. In the disclosure, one intelligent agent module is implemented for each deep reinforcement learning model. The disclosure implements intelligent agents in all three AI frameworks, such as PyTorch, TensorFlow and MindSpore. The one-to-one corresponding relationships among the parameters of the policies, learners, and intelligent agents are shown in Table 2.

TABLE 2
Corresponding relationship among the parameters
of policies, learners, and intelligent agents

| Policy | Learner | Intelligent agent |
|---|---|---|
| DQN | DQN_Learner | DQN_Agent |
| DDQN | DDQN_Learner | DDQN_Agent |
| DuelDON | DuelDQN_Learner | DuelDQN_Agent |
| C51 | C51_Learner | C51_Agent |
| DDPG | DDPG_Learner | DDPG_Agent |
| TD3 | TD3_Learner | TD3_Agent |
| SAC | SAC_Learner | SAC_Agent |
| PG | PG_Learner | PG_Agent |
| A2C | A2C_Learner | A2C_Agent |
| PPO | PPO_Learner | PPO_Agent |
| VDN | VDN_Learner | VDN_Agent |
| QMIX | QMIX_Learner | QMIX_Agent |
| WQMIX | WQMIX_Learner | WQMIX_Agent |
| DCG | DCG_Learner | DCG_Agent |
| MAPPO | MAPPO_Learner | MAPPO_Agent |
| MADDPG | MADDPG_Learner | MADDPG_Agent |

The original environment module in the disclosure stores original environment definitions for different simulation environments, including parameter acquisition, environment reset, action execution, environment rendering and global state acquisition functions of the original environment, and provides the environment vectorization module, the environments maker, the intelligent agent and the policy module with basic tools and parameters for simulation environment interaction. Considering the specificity of some simulation environments, users need to add some extra functions required for specific environments to the original environment module, so as to standardize the definition of member variables of each original environment module and ensure the consistency of the input/output interfaces of member functions. There is a synergistic relationship between the original environment module and environment vectorization module, which provides the environment vectorization module with the basic tools and parameters required for the simulation tasks.

In order to improve the sampling efficiency of the intelligent agent, the traditional single environment operation method has a slow sampling speed. In this intelligent decision-making platform, users can choose to adopt environment vectorization module, which randomly instantiate multiple environments to run in parallel based on the original environment module, so as to ensure the diversity of empirical data. The environment vectorization encapsulation ensures the consistency of formats and interfaces between environments, so as to ensure the compatibility of the same deep reinforcement learning model in different environments or tasks. The intelligent agent is allowed to interact with multiple environments at the same time.

The environments makers in the disclosure make specific simulation environments according to different simulation scenarios and task requirements so that the intelligent agent can interact with the environments makers and collect empirical data. Since different simulation environments correspond to different maps, scenarios or tasks, the instantiation parameters of one simulation scenario are divided into two parts: environment name and environment identifier. In the parameter configuration module, the environment name and the environment identifier are determined by specifying the two parameters of env_name and env_id, respectively. The parameter files of each deep reinforcement learning model under each task will also be stored in this classification method, so that the developers can locate the parameter positions quickly and avoid parameter misalignment. As shown in Table 3, in the parameter configuration file of each deep reinforcement learning model, the user needs to specify the environment name (env_name) and environment identifier (env_id). The naming method and the environment instantiation method is compatible with most simulation environments and is somewhat universal.

TABLE 3
Examples of naming methods of environment
name and environment identifier

| Environment | env_name | env_id |
|---|---|---|
| Atari environment | “atari” | “ALE/Breakout-v5” |
| MuJoCo environment | “mujoco” | “Ant-v4” |
| sc2 environment | “sc2” | “2m_vs_1z” |
| mpe environment | “mpe” | “simple_adversary_v3” |

The mathematical utilities module in the disclosure unifiedly encapsulates nonlinear functions, optimizers, and filters involved in various deep reinforcement learning models, which are individually written according to each AI framework but shared by various modules under that AI framework, and is mainly responsible for probability distribution-related calculations in the policy module, and the related functions in the learner module involving the optimizers.

In the disclosure, the runner drives the training process and testing process by controlling the interaction between the intelligent agent and the environment. The runner is provided with a training mode and a test mode. The training mode makes the parallel environments and the intelligent agent through the run method to train the deep reinforcement learning model, so as to produce the training result. The test mode makes the parallel environments and the intelligent agent through the benchmark method to enable performance testing of the deep reinforcement learning model, so as to produce a performance testing result. The disclosure can implement the runner under three AI frameworks of PyTorch, TensorFlow and MindSpore.

The intelligent decision-making platform in the disclosure contains 35 mainstream deep reinforcement learning models and more than 40 types of variants of such models, and can support three mainstream deep learning frameworks (PyTorch, TensorFlow, and MindSpore) at the same time. Table 4 shows the technical comparison between the intelligent decision-making platform of the present disclosure and some deep reinforcement learning decision-making platforms in the prior art.

TABLE 4
Comparison between the intelligent decision-making platform
of the present disclosure and some deep reinforcement
learning decision-making platforms in the prior art

| | | | | Intelligent |
|---|---|---|---|---|
| | | | | decision- |
| | | | | making |
| | | | | platform |
| | | | | provided |
| Indicator | RLlib | ChainerRL | Tianshou | herein |
| Number of | 30 | 24 | 30 | 35 |
| supported deep | | | | |
| reinforcement | | | | |
| learning models | | | | |
| Support for | ✓ | x | ✓ | ✓ |
| PyTorch | | | | |
| Support for | ✓ | x | x | ✓ |
| TensorFlow | | | | |
| Support for | x | x | x | ✓ |
| MindSpore | | | | |

The disclosure optimizes the reproduction method of deep reinforcement learning. The representer+policy+learner+intelligent agent architectural approach makes the implementation method of deep reinforcement learning models more flexible, fully considers various training techniques of deep reinforcement learning, and greatly improves the algorithm performance. Therefore, the algorithms supported by the intelligent decision-making platform of the disclosure all perform reliably, and perform well in some mainstream simulation environments such as MuJoCo and Atari games. Most of the deep reinforcement learning models outperform the benchmarks of platforms in the prior art.

Table 5 and Table 6 list the performance of some scenarios of the intelligent decision-making platform in MuJoCo and Atari environments, respectively. In Table 5, four deep reinforcement learning model algorithms of DDPG, TD3, A2C, and PPO are selected to test eight scenarios, such as Ant, HalfCheetah, Hopper, Walker2D, Swimmer, Reacher, Ipendulum, and IDPendulum, in the MuJoCo environment. After 1,000,000 steps of training for each algorithm, the average cumulative reward value per episode during which the intelligent agent policy interacts with the environment is recorded, and the reward value is used as the final test result. According to the final test results in Table 5, in all 8 scenarios of the MuJoCo environment, the performance of the DDPG algorithm in the intelligent decision-making platform of the disclosure meets or even exceeds the benchmark performance. The TD3 algorithm meets or exceeds the benchmark performance in 5 scenarios. The A2C algorithm meets or exceeds the benchmark performance in 7 scenarios. The PPO algorithm meets or exceeds the benchmark performance in 7 scenarios. Therefore, it could be concluded that the training results of the intelligent decision-making platform of the disclosure in the MuJoCo environment have a greater advantage compared with the training results of the prior art. The formula for calculating the test results is as follows:

$$G = \frac{1}{N} {Σ}_{i = 1}^{N} {Σ}_{T = 1}^{{T}^{i}} {r}_{t}^{i} .$$

In the above formula, N denotes the number of episodes; i denotes an index of N; G denotes the average cumulative reward of each episode; Tⁱ is the length of the i-th episode; t denotes the moment; rₜⁱ denotes the reward value that the environment feeds back to the intelligent agent at moment t in the i-th episode.

The test results in Table 6 are calculated in the same way as in Table 5. The difference between Table 6 and Table 5 is that each algorithm in Table 6 is trained for 10,000,000 steps, and two algorithms, DQN and PPO, are selected for testing seven scenarios in the Atari environment, namely AirRaid, Alien, Bowling, Breakout, Feeway, Pong, and Qbert. According to the final test results in Table 6, the DQN algorithm of the intelligent decision-making platform of the disclosure exceeds the benchmark performance in six of the seven scenarios in the Atari environment; and the PPO algorithm of the intelligent decision-making platform of the disclosure all exceeds the benchmark performance in the seven scenarios in the Atari environment. Therefore, it could be concluded that the training results of the intelligent decision-making platform of the disclosure in the Atari environment have a greater advantage compared to the training results of the prior art. The benchmark performances in Table 5 and Table 6 are referenced from the training results in the prior art.

TABLE 5
Performances of the intelligent decision-making platform of the present disclosure in MuJoCo environment

| | DDPG | | TD3 | | A2C | | PPO | |
|---|---|---|---|---|---|---|---|---|
| Environment | The | | The | | The | | The | |
| identifier | disclosure | Benchmark | disclosure | Benchmark | disclosure | Benchmark | disclosure | Benchmark |
| Ant | 1472.8 | 1005.3 | 4822.9 | 4372.4 | 1420.4 | — | 2810.7 | — |
| HalfCheetah | 10093 | 3305.6 | 10718.1 | 9637 | 2674.5 | 1000 | 4628.4 | 1800 |
| Hopper | 3434.9 | 2020.5 | 3492.4 | 3564.1 | 825.9 | 900 | 3450.1 | 2330 |
| Walker2D | 2443.7 | 1843.6 | 4307.9 | 4682.8 | 970.6 | 850 | 4318.6 | 3460 |
| Swimmer | 67.7 | — | 59.9 | — | 51.4 | 31 | 108.9 | 108 |
| Reacher | −5.05 | −6.5 | −4.07 | −3.6 | −11.7 | −24 | −8.1 | −7 |
| IPendulum | 1000.0 | 1000.0 | 1000.0 | 1000.0 | 1000.0 | 1000.0 | 1000.0 | 1000.0 |
| IDPendulum | 9359.8 | 9355.5 | 9358.9 | 9337.5 | 9357.8 | 8100 | 9359.1 | 8000 |

TABLE 6
Partial performances of the intelligent decision-making
platform of the present disclosure in Atari environment

| | DQN algorithm | | PPO algorithm | |
|---|---|---|---|---|
| Environment | The | | The | |
| identifier | disclosure | Benchmark | disclosure | Benchmark |
| AirRaid | 7316.67 | — | 9283.33 | — |
| Alien | 2676.67 | 3069 | 2313.33 | 1850.3 |
| Bowling | 92.0 | 42.4 | 76.0 | 40.1 |
| Breakout | 415.33 | 401.2 | 371.67 | 274.8 |
| Feeway | 34.0 | 30.3 | 34.0 | 32.5 |
| Pong | 21.0 | 18.9 | 21.0 | 20.7 |
| Qbert | 16350.0 | 10596 | 20050.0 | 14293.3 |

### Embodiment 1 Implementation of DQN Algorithm in Atari Game

### (Step 1)

The parameter file is configured and stored in “xuanpolicy/configs/dqn/atari.yaml”. The parameters are configured in the YAML file format, i.e., the form of “variable name: value”, and the value could only be a string or a number. The name, explanation, and value of individual parameters are shown in Table 7.

TABLE 7
Parameter setting for DQN algorithm in Atari games

| | Corresponding | |
|---|---|---|
| Variable name | parameter | Value |
| agent | Agent | “DQN” |
| vectorize | Parallel environment | “Dummy_Atari” |
| env_name | Environment name | “Atari” |
| env_id | Environment identifier | “ALE/Breakout-v5” |
| obs_type | Type of observation image | “grayscale” |
| img_size | Size of observation image | [84, 84] |
| num_stack | Number of frame stacks | 4 |
| frame_skip | Number of frame skips | 4 |
| noop_max | Maximum number of steps to perform | 30 |
| | no operations | |
| policy | Type of policy network | “Basic_Q_network” |
| representation | Type of representer | “Basic_CNN” |
| filters | Number of filters in a convolutional | [32, 64, 64] |
| | layer | |
| kernels | Kernel size of the convolutional layer | [8, 4, 3] |
| strides | Stride size of the convolutional layer | [4, 2, 1] |
| q_hidden_size | Size of a hidden layer in Q-network | [512,] |
| activation | Activation function | “ReLU” |
| seed | Random seeds | 1069 |
| parallels | Number of environments run in parallel | 5 |
| n_size | Size of experience replay buffer | 100000 |
| batch_size | Size of sample batch drawn from the | 32 |
| | experience replay buffer | |
| learning_rate | Learning rate | 0.0001 |
| gamma | Discount factor | 0.99 |
| start_greedy | Start greedy rate of ε-greedy policy | 0.5 |
| end_greedy | End greedy rate of the ε-greedy policy | 0.05 |
| decay_step_greedy | Number of steps with the decaying | 1000000 |
| | greedy rate | |
| sync_frequency | Synchronization frequency of target | 500 |
| | network | |
| training_frequency | Training frequency | 1 |
| running_steps | Total number of running steps | 50000000 |
| start_training | Number of steps to start training | 10000 |
| use_obsnorm | Whether to use observation | False |
| | normalization | |
| use_rewnorm | Whether to use reward normalization | False |
| obsnorm_range | Range of observation normalization | 5 |
| rewnorm_range | Range of reward normalization | 5 |
| test_steps | Number of test steps | 10000 |
| eval_interval | Evaluation interval | 500000 |
| test_episode | Number of test episodes | 3 |
| log_dir | Log file save path | “./logs/dqn/” |
| model_dir | Model file save path | “./models/dqn/” |

### (Step 2)

The general-purpose module reads the parameter file in Step 1 to get the dictionary type variable. Then the dictionary type variable is converted to “SimpleNamespace” type by using the types tool. The “key” and “value” of the original dictionary variable are used as the member variable name and the variable value of this type respectively.

### (Step 3)

The original environment type “Gym_Env” is created, which is inherited from the “gym. Wrapper” type. In this type, member variables of “env” (environment), “observation_space” (observation space), “action_space” (action space), “reward_range” (reward range), “_episode_step” (episode length) and “_episode_score” (episode cumulative rewards) are defined. At the same time, member functions of “close” (close environment), “render” (render current environment), “reset” (reset current environment) and “step” (execute environment) are defined.

### (Step 4)

The parallel environment type “Dummy VecEnv_Gym” is created based on the original environment type “Gym_Env” from step 3. In this type, multiple environments are instantiated at the same time; member variables of “envs” (environment list), “obs_shape” (state dimension), “buf_obs” (state buffer), “buf_dones” (termination buffer), “buf_trunctions” (truncation buffer), “buf_rews” (rewards buffer), “buf_infos” (environment information buffer), “action” and “max_episode_length” (maximum episode length) are defined; and member functions of “reset” (batch reset), “step_async” (synchronization execution) and “step_wait” (synchronization wait) are defined. All the environments makers need to be manipulated accordingly in the member functions.

### (Step 5)

The representer is created using state dimension of the parallel environment type from step 4 as input dimension. The appropriate representer is selected according to observed inputs of the environment. Taking multilayer perceptron as an example, it is necessary to specify input data dimension of the module, the number of nodes in the hidden layer, normalization method, initialization method, activation function, and choice of the computational hardware, and then build the neural network module. The module takes the last hidden layer as the output, so the dimension of the output is the same as the number of nodes in the last hidden layer.

### (Step 6)

The feature of the representer output from step 5 is obtained as input to create a policy. The policy takes the state of the hidden layer output by the representer as input and outputs information such as actions and value functions by creating the corresponding neural network structure. Therefore, the action space, the representer, the number of hidden layer nodes of the actuator, the number of evaluator hidden layer nodes, the normalization method, the initialization method, the activation function, and the computational hardware selection need to be specified in this module. Based on this, the actuator and evaluator are built. The actuator is used to output the action, and the evaluator is used to output the value function.

### (Step 7)

The learner type “DQN_Learner” is created. Before building this module, it needs to prepare the policy in step 6, select and create the optimizer from the mathematical utilities module, and determine the model storage path parameters. The core aspect of the module is the update (model update) of member functions which are responsible for calculating the model loss and the objective function, and the model parameters are updated based on the model loss and the objective function.

### (Step 8)

The intelligent agent type “DQN_Agent” is created. This module contains the learner created in step 7, obtains action-selection policy by the learner, and uses the policy to interact with the environment. In this module, member variables of “render” (whether to render the screen or not), “parallels” (number of parallel environments), “running_steps” (total number of running steps) and “batch_size” (batch sampling size) need to be defined. In addition, the learner from step 7 is instantiated, and the experience replay pool is created. On this basis, the “_action (obs)” member function is defined, which takes observation “obs” as input and outputs the action. The “train” (train_steps) member function is defined, after specifying the number of training steps, the cyclic operation of interaction-storage-sampling-training is realized, and the model parameters are continuously iterated. Accordingly, the “test” member functions also need to be defined to test the performance of the model.

### (Step 9)

The runner type “Runner_DRL” is defined. This module first receives the variable parameters obtained in step 2, determines information such as “agent_name, env_id”, and instantiates the parallel environment in step 4. Then, this module instantiates the representer in step 5 and passes the representer into the policy, thereby further instantiating the policy type in step 6. Then, the optimizer is defined for updating the neural network parameter and passes them into the intelligent agent type in step 8, thereby instantiating the intelligent agent type in step 8. Finally, the “run” and “benchmark” member functions in the runner are defined for training/testing the model, and obtaining the model benchmark performance, respectively.

Using DQN algorithm in this platform in the Atari environment has the following advantages.
(1) The parameters are configured uniformly in step 1, which makes it easy to observe the effect of different parameters on the performance of the algorithm.
(2) The module selection is more independent, which facilitates debugging of the various functions of the algorithm and facilitates the selection of the best parameters.
(3) The logic between modules is clear, and task deployment is faster.
(4) Implementation case steps are simple and uniform, and each implementation case can be used as a reference for the implementation of other cases.

For other AI frameworks, the DQN algorithm is compatible with the framework by repeating the above 9 steps. The above are the steps of building a decision-making platform including DQN algorithm. These steps can be repeated to expand other deep reinforcement learning algorithms and their simulation environments.

### Embodiment 2 Implementation of PPO Algorithm in the Atari Game

### (Step 1)

The parameter file is configured and stored in “xuanpolicy/configs/ppo/atari.yaml”. The parameters are configured in the YAML format, i.e., the form of “variable name: value”, and the value could only be a string or a number. The name, explanation, and value of individual parameters are shown in Table 8.

TABLE 8
Parameter setting for PPO algorithm in Atari games

| | Corresponding | |
|---|---|---|
| Variable name | parameter | Value |
| agent | Agent | “PPO_Clip” |
| vectorize | Parallel environment | “Dummy_Atari” |
| env_name | Environment name | “Atari” |
| env_id | Environment identifier | “ALE/Breakout-v5” |
| obs_type | Type of observation image | “grayscale” |
| img_size | Size of observation image | [84, 84] |
| num_stack | Number of frame stacks | 4 |
| frame_skip | Number of frame skips | 4 |
| noop_max | Maximum number of steps to | 30 |
| | perform no operations | |
| policy | Type of policy network | “Categorical_AC” |
| representation | Type of representer | “AC_CNN_Atari” |
| filters | Number of filters in a | [32, 64, 64] |
| | convolutional layer | |
| kernels | Kernel size of the | [8, 4, 3] |
| | convolutional layer | |
| strides | Stride size of the | [4, 2, 1] |
| | convolutional layer | |
| fc_hidden_size | Size of a hidden layer in fully | [512,] |
| | connected layer | |
| activation | Activation function | “ReLU” |
| seed | Random seeds | 1069 |
| parallels | Number of environments run | 8 |
| | in parallel | |
| running_steps | Total number of running | 10000000 |
| | steps | |
| n_steps | The number of steps per | 128 |
| | training batch | |
| n_epoch | The number of epoch trained | 4 |
| n_minibatch | Number of training batches | 100000 |
| | in each epoch | |
| learning_rate | Learning rate | 0.0001 |
| use_grad_clip | Whether to use gradient | 0.5 |
| | clipping | |
| vf_coef | Value function coefficient of | 0.25 |
| | loss function | |
| ent_coef | Information entropy | 0.01 |
| | coefficient of loss function | |
| clip_range | Clipping range | 0.2 |
| clip_grad_norm | Threshold for gradient | 0.5 |
| | clipping | |
| gamma | Discount factor | 0.99 |
| use_gae | Whether to use generalized | True |
| | dominant estimation | |
| gae_lambda | Parameter λ in generalized | 0.95 |
| | dominant estimation | |
| use_adv_norm | Whether to use dominant | True |
| | function normalization | |
| use_obsnorm | Whether to use observation | True |
| | normalization | |
| use_rewnorm | Whether to use reward | True |
| | normalization | |
| obsnorm_range | Range of observation | 5 |
| | normalization | |
| rewnorm_range | Range of reward | 5 |
| | normalization | |
| test_steps | Number of test steps | 10000 |
| eval_interval | Evaluation interval | 100000 |
| test_episode | Number of test episodes | 3 |
| log_dir | Log file save path | “./logs/ppo/” |
| model_dir | Model file save path | “./models/ppo/” |

### (Step 2)

The general-purpose module reads the parameter file in Step 1 to get the dictionary type variable. Then the dictionary type variable is converted to “SimpleNamespace” type by using the types tool. The “key” and “value” of the original dictionary variable are used as the member variable name and the variable value of this type respectively.

### (Step 3)

According to the “env_name” and “env_id” parameters read in Step 2, the original environment type “Gym_Env” is created which is inherited from the “gym. Wrapper” type. In this type, member variables of “env” (environment), “observation_space” (observation space), “action_space” (action space), “reward_range” (reward range), “_episode_step” (episode length) and “_episode_score” (episode cumulative rewards) are defined. At the same time, member functions of “close” (close environment), “render” (render current environment), “reset” (reset current environment) and “step” (execute environment) are defined.

### (Step 4)

The parallel environment type “Dummy VecEnv_Gym” is created based on the original environment type “Gym_Env” from step 3. In this type, multiple environments are instantiated at the same time; member variables of “envs” (environment list), “obs_shape” (state dimension), “buf_obs” (state buffer), “buf_dones” (termination buffer), “buf_trunctions” (truncation buffer), “buf_rews” (rewards buffer), “buf_infos” (environment information buffer), “action” and “max_episode_length” (maximum episode length) are defined; and member functions of “reset” (batch reset), “step_async” (synchronization execution) and “step_wait” (synchronization wait) are defined. All the environments makers need to be manipulated accordingly in the member functions.

### (Step 5)

The representer is created using state dimension of the parallel environment type from step 4 as input dimension. The appropriate representer is selected according to observed inputs of the environment. Taking multilayer perceptron as an example, it is necessary to specify input data dimension of the module, the number of nodes in the hidden layer, normalization method, initialization method, activation function, and choice of the computational hardware, and then build the neural network module. The module takes the last hidden layer as the output, so the dimension of the output is the same as the number of nodes in the last hidden layer.

### (Step 6)

The feature of the representer output from step 5 is obtained as input to create a policy. The policy takes the state of the hidden layer output by the representer as input and outputs information such as actions and value functions by creating the corresponding neural network structure. Therefore, the action space, the representer, the number of hidden layer nodes of the actuator, the number of evaluator hidden layer nodes, the normalization method, the initialization method, the activation function, and the computational hardware selection need to be specified in this module. Based on this, the actuator and evaluator are built. The actuator is used to output the action, and the evaluator is used to output the value function.

### (Step 7)

The learner type “PPO_Learner” is created. Before building this module, it needs to prepare the policy in step 6, select and create the optimizer from the mathematical utilities module, and determine the model storage path parameters. The core aspect of the module is the update (model update) of member functions which are responsible for calculating the model loss and the objective function, and the model parameters are updated based on the model loss and the objective function.

### (Step 8)

The intelligent agent type “PPO_Agent” is created. This module contains the learner created in step 7, obtains the action-selection policy by the learner, and uses the policy to interact with the environment. In this module, member variables of “render” (whether to render the screen or not), “parallels” (number of parallel environments), “running_steps” (total number of running steps) and “n_minibatch” (batch sampling number) need to be defined. In addition, the learner from step 7 is instantiated, and the experience replay pool is created. On this basis, the “_action (obs)” member function is defined, which takes observation “obs” as input and outputs the action. The “train” (train_steps) member function is defined, after specifying the number of training steps, the cyclic operation of interaction-storage-sampling-training is realized, and the model parameters are continuously iterated. Accordingly, the “test” member functions also need to be defined to test the performance of the model.

### (Step 9)

The runner type “Runner_DRL” is defined. This module first receives the variable parameters obtained in step 2, determines information such as “agent_name, env_id”, and instantiates the parallel environment in step 4. Then, this module instantiates the representer in step 5 and passes the representer into the policy, thereby further instantiating the policy type in step 6. Then, the optimizer is defined for updating the neural network parameter and passes them into the intelligent agent type in step 8, thereby instantiating the intelligent agent type in step 8. Finally, the “run” and “benchmark” member functions in the runner are defined for training/testing the model, and obtaining the model benchmark performance, respectively.

Using the PPO algorithm in this platform in the Atari environment has the following advantages.
(1) The parameters are configured uniformly in step 1, which makes it easy to observe the effect of different parameters on the performance of the algorithm.
(2) The module selection is more independent, which facilitates debugging of the various functions of the algorithm and facilitates the selection of the best parameters.
(3) The logic between modules is clear, and task deployment is faster.
(4) Implementation case steps are simple and uniform, and each implementation case can be used as a reference for the implementation of other cases.

For other AI frameworks, the DQN algorithm is compatible with the framework by repeating the above nine steps. The above are the steps of building a decision-making platform including PPO algorithm. These steps can be repeated to expand other deep reinforcement learning algorithms and their simulation environments.

### Embodiment 3 Implementation of DDPG Algorithm in the MuJoCo Environment

### (Step 1)

The parameter file is configured and stored in “xuanpolicy/configs/ddpg/mujoco.yaml”. The parameters are configured in the YAML format, i.e., the form of “variable name: value”, and the value could only be a string or a number. The name, explanation, and value of individual parameters are shown in Table 9.

TABLE 9
Parameter setting for DDPG algorithm in MuJoCo environment

| | Corresponding | |
|---|---|---|
| Variable name | parameter | Value |
| agent | Agent | “DDPG” |
| env_name | Environment name | “MuJoCo” |
| env_id | Environment identifier | “Ant-v4” |
| policy | Type of policy network | “DDPG_Policy” |
| representation | Type of representer | “Basic_Identical” |
| actor_hidden_size | Size of a hidden layer in | [256,] |
| | actor network | |
| critic_hidden_size | Size of the hidden layer in | [256,] |
| | critic network | |
| activation | Activation function | “LeakyReLU” |
| seed | Random seeds | 19089 |
| parallels | Number of environments | 4 |
| | to run in parallel | |
| n_size | Size of empirical replay | 50000 |
| | buffer | |
| batch_size | Size of sample batch | 256 |
| | drawn from the | |
| | experience replay buffer | |
| actor_learning_rate | Learning rate of actor | 0.001 |
| | network | |
| critic_learning_rate | Learning rate of critic | 0.001 |
| | network | |
| gamma | Discount factor | 0.99 |
| tau | Weight factor | 0.01 |
| start_noise | Start intensity of noise | 0.5 |
| end_noise | End intensity of noise | 0.01 |
| training_frequency | Training frequency | 1 |
| running_steps | Total number of running | 250000 |
| | steps | |
| start_training | Number of steps of start | 10000 |
| | training | |
| use_obsnorm | Whether to use | False |
| | observation normalization | |
| use_rewnorm | Whether to use reward | False |
| | normalization | |
| obsnorm_range | Range of observation | 5 |
| | normalization | |
| rewnorm_range | Range of reward | 5 |
| | normalization | |
| test_steps | Number of test steps | 10000 |
| eval_interval | Evaluation interval | 5000 |
| test_episode | Number of test episodes | 5 |
| log_dir | Log file save path | “./logs/ddpg/” |
| model_dir | Model file save path | “./models/ddpg/” |

### (Step 2)

The general-purpose module reads the parameter file in Step 1 to get the dictionary type variable. Then the dictionary type variable is converted to “SimpleNamespace” type by using the types tool. The “key” and “value” of the original dictionary variable are used as the member variable name and the variable value of this type respectively.

### (Step 3)

According to the “env_name” and “env_id” parameters read in Step 2, the original environment type “Gym_Env” is created which is inherited from the “gym. Wrapper” type. In this type, member variables of “env” (environment), “observation_space” (observation space), “action_space” (action space), “reward_range” (reward range), “_episode_step” (episode length) and “_episode_score” (episode cumulative rewards) are defined. At the same time, member functions of “close” (close environment), “render” (render current environment), “reset” (reset current environment) and “step” (execute environment) are defined.

### (Step 4)

The parallel environment type “Dummy VecEnv_Gym” is created based on the original environment type “Gym_Env” from step 3. In this type, multiple environments are instantiated at the same time; member variables of “envs” (environment list), “obs_shape” (state dimension), “buf_obs” (state buffer), “buf_dones” (termination buffer), “buf_trunctions” (truncation buffer), “buf_rews” (rewards buffer), “buf_infos” (environment information buffer), “action” and “max_episode_length” (maximum episode length) are defined; and member functions of “reset” (batch reset), “step_async” (synchronization execution) and “step_wait” (synchronization wait) are defined. All the environments makers need to be manipulated accordingly in the member functions.

### (Step 5)

The representer is created using state dimension of the parallel environment type from step 4 as input dimension. The appropriate representer is selected according to observed inputs of the environment. Taking multilayer perceptron as an example, it is necessary to specify input data dimension of the module, the number of nodes in the hidden layer, normalization method, initialization method, activation function, and choice of the computational hardware, and then build the neural network module. The module takes the last hidden layer as the output, so the dimension of the output is the same as the number of nodes in the last hidden layer.

### (Step 6)

The feature of the representer output from step 5 is obtained as input to create a policy. The policy takes the state of the hidden layer output by the representer as input and outputs information such as actions and value functions by creating the corresponding neural network structure. Therefore, the action space, the representer, the number of hidden layer nodes of the actuator, the number of evaluator hidden layer nodes, the normalization method, the initialization method, the activation function, and the computational hardware selection need to be specified in this module. Based on this, the actuator and evaluator are built. The actuator is used to output the action, and the evaluator is used to output the value function.

### (Step 7)

The learner type “DDPG_Learner” is created. Before building this module, it needs to prepare the policy in step 6, select and create the optimizer from the mathematical utilities module, and determine the model storage path parameters. The core aspect of the module is the update (model update) of member functions which are responsible for calculating the model loss and the objective function, and the model parameters are updated based on the model loss and the objective function.

### (Step 8)

The intelligent agent type “DDPG_Agent” is created. This module contains the learner created in step 7, obtains action-selection policy by the learner, and uses the policy to interact with the environment. In this module, member variables of “render” (whether to render the screen or not), “parallels” (number of parallel environments), “running_steps” (total number of running steps) and “batch_size” (batch sampling size) need to be defined. In addition, the learner from step 7 is instantiated, and the experience replay pool is created. On this basis, the “_action (obs)” member function is defined, which takes observation “obs” as input and outputs the action. The “train” (train_steps) member function is defined, after specifying the number of training steps, the cyclic operation of interaction-storage-sampling-training is realized, and the model parameters are continuously iterated. Accordingly, the “test” member functions also need to be defined to test the performance of the model.

### (Step 9)

The runner type “Runner_DRL” is defined. This module first receives the variable parameters obtained in step 2, determines information such as “agent_name, env_id”, and instantiates the parallel environment in step 4. Then, this module instantiates the representer in step 5 and passes the representer into the policy, thereby further instantiating the policy type in step 6. Then, the optimizer is defined for updating the neural network parameter and passes them into the intelligent agent type in step 8, thereby instantiating the intelligent agent type in step 8. Finally, the “run” and “benchmark” member functions in the runner are defined for training/testing the model, and obtaining the model benchmark performance, respectively.

Using the DDPG algorithm in this platform in the MuJoCo environment has the following advantages.
(1) The parameters are configured uniformly in step 1, which makes it easy to observe the effect of different parameters on the performance of the algorithm.
(2) The module selection is more independent, which facilitates debugging of the various functions of the algorithm and facilitates the selection of the best parameters.
(3) The logic between modules is clear, and task deployment is faster.
(4) Implementation case steps are simple and uniform, and each implementation case can be used as a reference for the implementation of other cases.

For other AI frameworks, the DDPG algorithm is compatible with the framework by repeating the above 9 steps. The above are the steps of building a decision-making platform including the DDPG algorithm. These steps can be repeated to expand other deep reinforcement learning algorithms and their simulation environments.

### Embodiment 4 Implementation of TD3 Algorithm in the MuJoCo Environment

### (Step 1)

The parameter file is configured and stored in “xuanpolicy/configs/td3/mujoco.yaml”. The parameters are configured in the YAML format, i.e., the form of “variable name: value”, and the value could only be a string or a number. The name, explanation, and value of individual parameters are shown in Table 10.

TABLE 10
Parameter setting of TD3 algorithm in MuJoCo environment

| | Corresponding | |
|---|---|---|
| Variable name | parameter | Value |
| agent | Agent | “TD3” |
| env_name | Environment name | “MuJoCo” |
| env_id | Environment identifier | “Ant-v4” |
| policy | Type of policy network | “TD3_Policy” |
| representation | Type of representer | “Basic_Identical” |
| actor_hidden_size | Size of a hidden layer in | [256,] |
| | actor network | |
| critic_hidden_size | Size of the hidden layer in | [256,] |
| | critic network | |
| activation | Activation function | “LeakyReLU” |
| seed | Random seeds | 6782 |
| parallels | Number of environments | 4 |
| | run in parallel | |
| n_size | Size of empirical replay | 50000 |
| | buffer | |
| batch_size | Size of sample batch | 256 |
| | drawn from the | |
| | experience replay buffer | |
| actor_learning_rate | Learning rate of actor | 0.001 |
| | network | |
| actor_update_decay | Number of update steps | 3 |
| | of actor network | |
| critic_learning_rate | Learning rate of critic | 0.001 |
| | network | |
| gamma | Discount factor | 0.99 |
| tau | Weight factor | 0.01 |
| start_noise | Start intensity of noise | 0.5 |
| end_noise | End intensity of noise | 0.01 |
| training_frequency | Training frequency | 1 |
| running_steps | Total number of running | 250000 |
| | steps | |
| start_training | Number of steps of start | 10000 |
| | training | |
| use_obsnorm | Whether to use | False |
| | observation normalization | |
| use_rewnorm | Whether to use reward | False |
| | normalization | |
| obsnorm_range | Range of observation | 5 |
| | normalization | |
| rewnorm_range | Range of reward | 5 |
| | normalization | |
| test_steps | Number of test steps | 10000 |
| eval_interval | Evaluation interval | 5000 |
| test_episode | Number of test episodes | 5 |
| log_dir | Log file save path | “./logs/td3/” |
| model_dir | Model file save path | “./models/td3/” |

### (Step 2)

The general-purpose module reads the parameter file in Step 1 to get the dictionary type variable. Then the dictionary type variable is converted to “SimpleNamespace” type by using the types tool. The “key” and “value” of the original dictionary variable are used as the member variable name and the variable value of this type respectively.

### (Step 3)

According to the “env_name” and “env_id” parameters read in Step 2, the original environment type “Gym_Env” is created which is inherited from the “gym. Wrapper” type. In this type, member variables of “env” (environment), “observation_space” (observation space), “action_space” (action space), “reward_range” (reward range), “_episode_step” (episode length) and “_episode_score” (episode cumulative rewards) are defined. At the same time, member functions of “close” (close environment), “render” (render current environment), “reset” (reset current environment) and “step” (execute environment) are defined.

### (Step 4)

The parallel environment type “Dummy VecEnv_Gym” is created based on the original environment type “Gym_Env” from step 3. In this type, multiple environments are instantiated at the same time; member variables of “envs” (environment list), “obs_shape” (state dimension), “buf_obs” (state buffer), “buf_dones” (termination buffer), “buf_trunctions” (truncation buffer), “buf_rews” (rewards buffer), “buf_infos” (environment information buffer), “action” and “max_episode_length” (maximum episode length) are defined; and member functions of “reset” (batch reset), “step_async” (synchronization execution) and “step_wait” (synchronization wait) are defined. All the environments makers need to be manipulated accordingly in the member functions.

### (Step 5)

The representer is created using state dimension of the parallel environment type from step 4 as input dimension. The appropriate representer is selected according to observed inputs of the environment. Taking multilayer perceptron as an example, it is necessary to specify input data dimension of the module, the number of nodes in the hidden layer, normalization method, initialization method, activation function, and choice of the computational hardware, and then build the neural network module. The module takes the last hidden layer as the output, so the dimension of the output is the same as the number of nodes in the last hidden layer.

### (Step 6)

The feature of the representer output from step 5 is obtained as input to create a policy. The policy takes the state of the hidden layer output by the representer as input and output information such as actions and value functions by creating the corresponding neural network structure. Therefore, the action space, the representer, the number of hidden layer nodes of the actuator, the number of evaluator hidden layer nodes, the normalization method, the initialization method, the activation function, and the computational hardware selection need to be specified in this module. Based on this, the actuator and evaluator are built. The actuator is used to output the action, and the evaluator is used to output the value function.

### (Step 7)

The learner type “TD3_Learner” is created. Before building this module, it needs to prepare the policy in step 6, select and create the optimizer from the mathematical utilities module, and determine the model storage path parameters. The core aspect of the module is the update of member functions which are responsible for calculating the model loss and the objective function, and the model parameters are updated based on the model loss and the objective function.

### (Step 8)

The intelligent agent type “TD3_Agent” is created. This module contains the learner created in step 7, obtains action-selection policy by the learner, and uses the policy to interact with the environment. In this module, member variables of “render” (whether to render the screen or not), “parallels” (number of parallel environments), “running_steps” (total number of running steps) and “batch_size” (batch sampling number) need to be defined. In addition, the learner from step 7 is instantiated, and the experience replay pool is created. On this basis, the “_action (obs)” member function is defined, which takes observation “obs” as input and outputs the action. The “train” (train_steps) member function is defined, after specifying the number of training steps, the cyclic operation of interaction-storage-sampling-training is realized, and the model parameters are continuously iterated. Accordingly, the “test” member functions also need to be defined to test the performance of the model.

### (Step 9)

The runner type “Runner_DRL” is defined. This module first receives the variable parameters obtained in step 2, determines information such as “agent_name, env_id”, and instantiates the parallel environment in step 4. Then, this module instantiates the representer in step 5 and passes the representer into the policy, thereby further instantiating the policy type in step 6. Then, the optimizer is defined for updating the neural network parameter and passes them into the intelligent agent type in step 8, thereby instantiating the intelligent agent type in step 8. Finally, the “run” and “benchmark” member functions in the runner are defined for training/testing the model, and obtaining the model benchmark performance, respectively.

Using the TD3 algorithm in this platform in the MuJoCo environment has the following advantages.
(1) The parameters are configured uniformly in step 1, which makes it easy to observe the effect of different parameters on the performance of the algorithm.
(2) The module selection is more independent, which facilitates debugging of the various functions of the algorithm and facilitates the selection of the best parameters.
(3) The logic between modules is clear, and task deployment is faster.
(4) Implementation case steps are simple and uniform, and each implementation case can be used as a reference for the implementation of other cases.

For other AI frameworks, the TD3 algorithm is compatible with the framework by repeating the above 9 steps. The above are the steps of building a decision-making platform including the TD3 algorithm. These steps can be repeated to expand other deep reinforcement learning algorithms and their simulation environments.

### Embodiment 5 Implementation of A2C Algorithm in the MuJoCo Environment

### (Step 1)

The parameter file is configured and stored in “xuanpolicy/configs/a2c/mujoco.yaml”. The parameters are configured in the YAML format, i.e., the form of “variable name: value”, and the value could only be a string or a number. The name, explanation, and value of individual parameters are shown in Table 11.

TABLE 11
Parameter setting of A2C Algorithm in MuJoCo Environment

| | Corresponding | |
|---|---|---|
| Variable name | parameter | Value |
| agent | Agent | “A2C” |
| env_name | Environment name | “MuJoCo” |
| env_id | Environment identifier | “Ant-v4” |
| policy | Type of policy network | “Gaussian_AC” |
| representation | Type of representer | “Basic_MLP” |
| actor_hidden_size | Size of a hidden layer in | [256,] |
| | actor network | |
| critic_hidden_size | Size of the hidden layer in | [256,] |
| | critic network | |
| activation | Activation function | “LeakyReLU” |
| seed | Random seeds | 6782 |
| parallels | Number of environments | 16 |
| | run in parallel | |
| running_steps | Total number of running | 1000000 |
| | steps | |
| n_steps | Number of steps per | 16 |
| | training batch | |
| n_epoch | Number of epoch trained | 1 |
| n_minibatch | Number of training | 1 |
| | batches in each epoch | |
| learning_rate | Learning rate | 0.0007 |
| vf_coef | Value function coefficient | 0.25 |
| | of loss function | |
| ent_coef | Information entropy | 0.0 |
| | coefficient of loss function | |
| clip_grad | Threshold for gradient | 0.5 |
| | clipping | |
| clip_type | Type for gradient clipping | 1 |
| gamma | Discount factor | 0.99 |
| use_gae | Whether to use | True |
| | generalized dominant | |
| | estimation | |
| gae_lambda | Parameter λ in generalized | 0.95 |
| | dominant estimation | |
| use_advnorm | Whether to use dominant | True |
| | function normalization | |
| use_obsnorm | Whether to use | True |
| | observation normalization | |
| use_rewnorm | Whether to use reward | True |
| | normalization | |
| obsnorm_range | Range of observation | 5 |
| | normalization | |
| rewnorm_range | Range of reward | 5 |
| | normalization | |
| test_steps | Number of test steps | 10000 |
| eval_interval | Evaluation interval | 10000 |
| test_episode | Number of test episodes | 5 |
| log_dir | Log file save path | “./logs/a2c/” |
| model_dir | Model file save path | “./models/a2c/” |

### Step (2)

The general-purpose module reads the parameter file in Step 1 to get the dictionary type variable. Then the dictionary type variable is converted to “SimpleNamespace” type by using the types tool. The “key” and “value” of the original dictionary variable are used as the member variable name and the variable value of this type respectively.

### (Step 3)

According to the “env_name” and “env_id” parameters read in Step 2, the original environment type “Gym_Env” is created which is inherited from the “gym. Wrapper” type. In this type, member variables of “env” (environment), “observation_space” (observation space), “action_space” (action space), “reward_range” (reward range), “_episode_step” (episode length) and “_episode_score” (episode cumulative rewards) are defined. At the same time, member functions of “close” (close environment), “render” (render current environment), “reset” (reset current environment) and “step” (execute environment) are defined.

### (Step 4)

The parallel environment type “Dummy VecEnv_Gym” is created based on the original environment type “Gym_Env” from step 3. In this type, multiple environments are instantiated at the same time; member variables of “envs” (environment list), “obs_shape” (state dimension), “buf_obs” (state buffer), “buf_dones” (termination buffer), “buf_trunctions” (truncation buffer), “buf_rews” (rewards buffer), “buf_infos” (environment information buffer), “action” and “max_episode_length” (maximum episode length) are defined; and member functions of “reset” (batch reset), “step_async” (synchronization execution) and “step_wait” (synchronization wait) are defined. All the environments makers need to be manipulated accordingly in the member functions.

### (Step 5)

The representer is created using state dimension of the parallel environment type from step 4 as input dimension. The appropriate representer is selected according to observed inputs of the environment. Taking multilayer perceptron as an example, it is necessary to specify input data dimension of the module, the number of nodes in the hidden layer, normalization method, initialization method, activation function, and choice of the computational hardware, and then build the neural network module. The module takes the last hidden layer as the output, so the dimension of the output is the same as the number of nodes in the last hidden layer.

### (Step 6)

The feature of the representer output from step 5 is obtained as input to create a policy. The policy takes the state of the hidden layer output by the representer as input and outputs information such as actions and value functions by creating the corresponding neural network structure. Therefore, the action space, the representer, the number of hidden layer nodes of the actuator, the number of evaluator hidden layer nodes, the normalization method, the initialization method, the activation function, and the computational hardware selection need to be specified in this module. Based on this, the actuator and evaluator are built. The actuator is used to output the action, and the evaluator is used to output the value function.

### (Step 7)

The learner type “A2C_Learner” is created. Before building this module, it needs to prepare the policy in step 6, select and create the optimizer from the mathematical utilities module, and determine the model storage path parameters. The core aspect of the module is the update of member functions which are responsible for calculating the model loss and the objective function, and the model parameters are updated based on the model loss and the objective function.

### (Step 8)

The intelligent agent type “A2C_Agent” is created. This module contains the learner created in step 7, obtains action-selection policy by the learner, and uses the policy to interact with the environment. In this module, member variables of “render” (whether to render the screen or not), “parallels” (number of parallel environments), “running_steps” (total number of running steps) and “n_minibatch” (the number of sampling mini-batches) need to be defined. In addition, the learner from step 7 is instantiated, and the experience replay pool is created. On this basis, the “_action(obs)” member function is defined, which takes observation “obs” as input and outputs the action. The “train” (train_steps) member function is defined, after specifying the number of training steps, the cyclic operation of interaction-storage-sampling-training is realized, and the model parameters are continuously iterated. Accordingly, the “test” member functions also need to be defined to test the performance of the model.

### (Step 9)

The runner type “Runner_DRL” is defined. This module first receives the variable parameters obtained in step 2, determines information such as “agent_name, env_id”, and instantiates the parallel environment in step 4. Then, this module instantiates the representer in step 5 and passes the representer into the policy, thereby further instantiating the policy type in step 6. Then, the optimizer is defined for updating the neural network parameter and passes them into the intelligent agent type in step 8, thereby instantiating the intelligent agent type in step 8. Finally, the “run” and “benchmark” member functions in the runner are defined for training/testing the model, and obtaining the model benchmark performance, respectively.

Using the A2C algorithm in this platform in the MuJoCo environment has the following advantages.
(1) The parameters are configured uniformly in step 1, which makes it easy to observe the effect of different parameters on the performance of the algorithm.
(2) The module selection is more independent, which facilitates debugging of the various functions of the algorithm and facilitates the selection of the best parameters.
(3) The logic between modules is clear, and task deployment is faster.
(4) Implementation case steps are simple and uniform, and each implementation case can be used as a reference for the implementation of other cases.

For other AI frameworks, the A2C algorithm is compatible with the framework by repeating the above 9 steps. The above are the steps of building a decision-making platform including the A2C algorithm. These steps can be repeated to expand other deep reinforcement learning algorithms and their simulation environments.

### Embodiment 6 Implementation of PPO Algorithm in MuJoCo Environment

### (Step 1)

The parameter file is configured and stored in “xuanpolicy/configs/ppo/mujoco.yaml”. The parameters are configured in the YAML format, i.e., the form of “variable name: value”, and the value could only be a string or a number. The name, explanation, and value of individual parameters are shown in Table 12.

TABLE 12
Parameter setting of PPO Algorithm in MuJoCo Environment

| | Corresponding | |
|---|---|---|
| Variable name | parameter | Value |
| agent | Agent | “PPO_Clip” |
| env_name | Environment name | “MuJoCo” |
| env_id | Environment identifier | “Ant-v4” |
| policy | Type of policy network | “Gaussian_AC” |
| representation | Type of representer | “Basic_MLP” |
| actor_hidden_size | Size of a hidden layer in | [256,] |
| | actor network | |
| critic_hidden_size | Size of the hidden layer | [256,] |
| | in critic network | |
| activation | Activation function | “LeakyReLU” |
| seed | Random seeds | 79811 |
| parallels | Number of environments | 16 |
| | run in parallel | |
| running_steps | Total number of running | 1000000 |
| | steps | |
| n_steps | Number of steps per | 256 |
| | training batch | |
| n_epoch | Number of epoch trained | 16 |
| n_minibatch | Number of training | 8 |
| | batches in each epoch | |
| learning_rate | Learning rate | 0.0004 |
| use_grad_clip | Whether to use gradient | True |
| | shear | |
| vf_coef | Value function | 0.25 |
| | coefficient of loss | |
| | function | |
| ent_coef | Information entropy | 0.0 |
| | coefficient of loss | |
| | function | |
| target_kl | Target KL divergence | 0.001 |
| clip_range | Clipping range | 0.2 |
| clip_grad_norm | Threshold for gradient | 0.5 |
| | clipping | |
| gamma | Discount factor | 0.99 |
| use_gae | Whether to use | True |
| | generalized dominant | |
| | estimation | |
| gae_lambda | Parameter λ in | 0.95 |
| | generalized dominant | |
| | estimation | |
| use_advnorm | Whether to use dominant | True |
| | function normalization | |
| use_obsnorm | Whether to use | True |
| | observation | |
| | normalization | |
| use_rewnorm | Whether to use reward | True |
| | normalization | |
| obsnorm_range | Range of observation | 5 |
| | normalization | |
| rewnorm_range | Range of reward | 5 |
| | normalization | |
| test_steps | Number of test steps | 10000 |
| eval_interval | Evaluation interval | 10000 |
| test_episode | Number of test episodes | 5 |
| log_dir | Log file save path | “./logs/ppo/” |
| model_dir | Model file save path | “./models/ppo/” |

### (Step 2)

The general-purpose module reads the parameter file in Step 1 to get the dictionary type variable. Then the dictionary type variable is converted to “SimpleNamespace” type by using the types tool. The “key” and “value” of the original dictionary variable are used as the member variable name and the variable value of this type respectively.

### (Step 3)

According to the “env_name” and “env_id” parameters read in Step 2, the original environment type “Gym_Env” is created which is inherited from the “gym. Wrapper” type. In this type, member variables of “env” (environment), “observation_space” (observation space), “action_space” (action space), “reward_range” (reward range), “_episode_step” (episode length) and “_episode_score” (episode cumulative rewards) are defined. At the same time, member functions of “close” (close environment), “render” (render current environment), “reset” (reset current environment) and “step” (execute environment) are defined.

### (Step 4)

The parallel environment type “Dummy VecEnv_Gym” is created based on the original environment type “Gym_Env” from step 3. In this type, multiple environments are instantiated at the same time; member variables of “envs” (environment list), “obs_shape” (state dimension), “buf_obs” (state buffer), “buf_dones” (termination buffer), “buf_trunctions” (truncation buffer), “buf_rews” (rewards buffer), “buf_infos” (environment information buffer), “action” and “max_episode_length” (maximum episode length) are defined; and member functions of “reset” (batch reset), “step_async” (synchronization execution) and “step_wait” (synchronization wait) are defined. All the environments makers need to be manipulated accordingly in the member functions.

### (Step 5)

The representer is created using state dimension of the parallel environment type from step 4 as input dimension. The appropriate representer is selected according to observed inputs of the environment. Taking multilayer perceptron as an example, it is necessary to specify input data dimension of the module, the number of nodes in the hidden layer, normalization method, initialization method, activation function, and choice of the computational hardware, and then build the neural network module. The module takes the last hidden layer as the output, so the dimension of the output is the same as the number of nodes in the last hidden layer.

### (Step 6)

The feature of the representer output from step 5 is obtained as input to create a policy. The policy takes the state of the hidden layer output by the representer as input and outputs information such as actions and value functions by creating the corresponding neural network structure. Therefore, the action space, the representer, the number of hidden layer nodes of the actuator, the number of evaluator hidden layer nodes, the normalization method, the initialization method, the activation function, and the computational hardware selection need to be specified in this module. Based on this, the actuator and evaluator are built. The actuator is used to output the action, and the evaluator is used to output the value function.

### (Step 7)

The learner type “PPO_Learner” is created. Before building this module, it needs to prepare the policy in step 6, select and create the optimizer from the mathematical utilities module, and determine the model storage path parameters. The core aspect of the module is the update of member functions which are responsible for calculating the model loss and the objective function, and the model parameters are updated based on the model loss and the objective function.

### (Step 8)

The intelligent agent type “PPO_Agent” is created. This module contains the learner created in step 7, obtains action-selection policy by the learner, and uses the policy to interact with the environment. In this module, member variables of “render” (whether to render the screen or not), “parallels” (number of parallel environments), “running_steps” (total number of running steps) and “n_minibatch” (the number of sampling mini-batches) need to be defined. In addition, the learner from step 7 is instantiated, and the experience replay pool is created. On this basis, the “_action (obs)” member function is defined, which takes observation “obs” as input and outputs the action. The “train” (train_steps) member function is defined, after specifying the number of training steps, the cyclic operation of interaction-storage-sampling-training is realized, and the model parameters are continuously iterated. Accordingly, the “test” member functions also need to be defined to test the performance of the model.

### (Step 9)

The runner type “Runner_DRL” is defined. This module first receives the variable parameters obtained in step 2, determines information such as “agent_name, env_id”, and instantiates the parallel environment in step 4. Then, this module instantiates the representer in step 5 and passes the representer into the policy, thereby further instantiating the policy type in step 6. Then, the optimizer is defined for updating the neural network parameter and passes them into the intelligent agent type in step 8, thereby instantiating the intelligent agent type in step 8. Finally, the “run” and “benchmark” member functions in the runner are defined for training/testing the model, and obtaining the model benchmark performance, respectively.

Using the PPO algorithm in this platform in the MuJoCo environment has the following advantages.
(1) The parameters are configured uniformly in step 1, which makes it easy to observe the effect of different parameters on the performance of the algorithm.
(2) The module selection is more independent, which facilitates debugging of the various functions of the algorithm and facilitates the selection of the best parameters.
(3) The logic between modules is clear, and task deployment is faster.
(4) Implementation case steps are simple and uniform, and each implementation case can be used as a reference for the implementation of other cases.

For other AI frameworks, the PPO algorithm is compatible with the framework by repeating the above 9 steps. The above are the steps of building a decision-making platform including the PPO algorithm. These steps can be repeated to expand other deep reinforcement learning algorithms and their simulation environments.

Described above are merely preferred embodiments of the disclosure, which are not intended to limit the disclosure. It should be understood that any modifications and replacements made by those skilled in the art without departing from the spirit of the disclosure should fall within the scope of the disclosure defined by the present claims.

What is claimed is:

1. A deep reinforcement learning intelligent decision-making platform based on a unified artificial intelligence (AI) framework, comprising:
a parameter configuration module;
a general-purpose module;
an original environment module;
an environment vectorization module;
an environments maker;
a mathematical utilities module;
a model library; and
a runner;
wherein the parameter configuration module is connected to the general-purpose module; the general-purpose module is connected to the model library, the original environment module and the runner; the original environment module, the environment vectorization module, and the environments maker are connected in turn; the environments maker is connected to the runner; and the mathematical utilities module is connected to the model library;
the parameter configuration module is configured to select parameters of a deep reinforcement learning model, comprising an intelligent agent name, a representer name, a policy name, a learner name, an algorithmic parameter, an environment name, and a system parameter;
the general-purpose module is configured to read the parameters of the deep reinforcement learning model; call and create a representer, a policy module, a learner, and an intelligent agent from the model library according to the parameters; and call a necessary function definition and an optimizer from the mathematical utilities module during a process of creating the policy module and the learner;
the environment vectorization module is configured to create parallel environments based on an original environment according to the parameters;
the environments maker is configured to make the parallel environments to obtain made environments, and input the made environments and the intelligent agent into the runner;
the runner is configured to compute an action output, and execute the action output in the made environments to realize intelligent decision-making;
the model library is configured to provide a user with the deep reinforcement learning model, and customize and optimize the deep reinforcement learning model according to different scenarios and task requirements;
the model library consists of the representer, the policy module, the learner, and the intelligent agent; the representer is configured to be determined based on a representation parameter read by a YAML file reading module, and convert raw observation data in the made environments into a feature suitable for being processed by the deep reinforcement learning model for representation;
the policy module is configured to determine a policy based on a policy parameter read by the YAML file reading module, and formulate a decision-making behavior adopted by the intelligent agent with the feature calculated by the representer as an input; the decision-making behavior comprises an action selection policy and an environment interaction mode;
the learner is configured to be determined based on a learner parameter read by the YAML file reading module, formulate a learning rule based on empirical data and the action selection policy, so as to obtain an action-selection policy;
the intelligent agent is configured to be determined based on an agent parameter read by the YAML file reading module, output an action and execute the decision-making behavior using the action-selection policy of the learner, and interact with a simulation environment;
the parameter configuration module is also configured to configure parameters involved in decision-making algorithms and tasks in a YAML format, and transfer configured parameters to the general-purpose module;
the general-purpose module is configured to store a programming module required by different decision-making algorithms for solving different decision-making problems; the general-purpose module is provided with the YAML file reading module, a terminal command reading module and an empirical data pool;
the YAML file reading module is configured to read a YAML file in the parameter configuration module, transfer a parameter read from the YAML file to the intelligent agent and the runner, transfer the parameter to the learner, the policy module, and the representer in turn through the intelligent agent, and transfer the parameter to the original environment module, the environment vectorization module, and the environments maker through the runner;
the terminal command reading module is configured to read a terminal command to support user's interaction with the deep reinforcement learning intelligent decision-making platform;
the empirical data pool is configured to store and manage empirical data from environment interactions; the empirical data pool is configured to be associated with the learner through the intelligent agent to support an experience replay training and optimization process of the learner;
the original environment module is configured to store original environment definitions for different simulation environments, comprising parameter acquisition, environment reset, action execution, environment rendering and global state acquisition functions of the original environment, and provide the environment vectorization module, the environments maker, the intelligent agent and the policy module with a basic tool and parameters for simulation environment interaction;
the environment vectorization module is configured to randomly create a plurality of environments to run in parallel according to the original environment to interact with the intelligent agent; and
the environments maker is configured to make a specific simulation environment according to the simulation scenarios and task requirements, to interact with the intelligent agent.

2. The deep reinforcement learning intelligent decision-making platform of claim 1, wherein the mathematical utilities module is configured to unifiedly encapsulate nonlinear functions, optimizers, and filters involved in various deep reinforcement learning models, and is responsible for probability distribution-related calculations in the policy module, and functions in the learner involving the optimizer.

3. The deep reinforcement learning intelligent decision-making platform of claim 2, wherein the runner is configured to have a training mode and a test mode; the training mode is configured to make the parallel environments and the intelligent agent through a run method to train the deep reinforcement learning model, so as to produce a training result; and the test mode is configured to make the parallel environments and the intelligent agent through a benchmark method to enable performance testing of the deep reinforcement learning model, so as to produce a performance testing result.
